(19) United States
(12) Patent Application Publication
(10) Pub. No.: US 2020/0251628 A1
(43) Pub. Date: Aug. 6, 2020

(54) SEMICONDUCTOR LIGHT EMITTING UNIT AND PACKAGING METHOD THEREOF

(71) Applicant: Primax Electronics Ltd., Taipei (TW)

(72) Inventors: Ya-Chin Tu, Taipei (TW); Hung-Wei Kuo, Taipei (TW); Yu-Zeng Yang, Taipei (TW)

(21) Appl. No.: 16/394,358

(22) Filed: Apr. 25, 2019

(30) Foreign Application Priority Data
Jan. 31, 2019 (TW) 108103891

(51) Int. Cl. H01L 33/52; H01L 33/00; H01L 33/02

(52) U.S. Cl. CPC H01L 33/52; H01L 2933/0033; H01L 33/02; H01L 33/005

(57) ABSTRACT

A semiconductor light emitting unit and a packaging method of the semiconductor light emitting unit are provided. The packaging method includes the following steps. In a step (a), a transparent substrate is provided. In a step (b), a transparent membrane circuit layer is formed on a surface of the transparent substrate. In a step (c), a semiconductor light emitting chip is formed on the transparent membrane circuit layer by a flip-chip mounting process, so that the semiconductor light emitting chip and the transparent membrane circuit layer are electrically connected with each other. In a step (d), an encapsulant is formed over the semiconductor light emitting chip to cover the semiconductor light emitting chip and a portion of the transparent membrane circuit layer. In a step (e), the encapsulant is baked.

### FIELD OF THE INVENTION

The present invention relates to a packaging technology, and more particularly to a semiconductor light emitting unit and a packaging method of the semiconductor light emitting unit.

### BACKGROUND OF THE INVENTION

A light emitting diode (LED) is a small and highly-luminous solid state light source that has been widely used in display modules or illumination modules of various types of electronic products. With the advancement and development of technology, the trends of designing electronic products are toward high performance and aesthetically-pleasing appearance. Generally, for designing a display module or an illumination module of an electronic device, the arrangement of the conductive wires or signal lines should be taken into consideration. Especially, for designing the electronic products with the appearance of transparency or high light transmittance as the main appeal, it is important to hide or arrange the conductive wires or signal lines in order to enhance the aesthetically-pleasing appearance of the electronic products.

Conventionally, the conductive wires or signal lines of the transparent display module or illumination module are made of metallic material. However, the arrangement of the metallic conductive wires or signal lines may influence the visual effect of the display module or the illumination module. Moreover, in the existing display module or illumination module, the semiconductor light emitting chip and the conductive wires are connected with each other through a wire bonding process. If the conductive wire is broken or the conductive wire is not well brazed during the wire bonding process, the production yield of the display module or illumination module is adversely affected. Moreover, while the conductive wire is brazed, the wire bonding tool may damage the semiconductor light emitting chip. Moreover, according to the conventional method of packaging the semiconductor light emitting chip, phosphor powder is usually added to the encapsulant. Once the phosphor powder adsorbs water and is heated, the luminous efficiency of the display module or illumination module is impaired.

For solving the above drawbacks, there is a need of providing a packaging method of a semiconductor light emitting unit in order to increase the production yield of the semiconductor light emitting unit and enhance its overall transparency.

### SUMMARY OF THE INVENTION

The present invention provides a semiconductor light emitting unit with high yield and high transparent and a packaging method of the semiconductor light emitting unit.

In accordance with an aspect of the present invention, a packaging method of a semiconductor light emitting unit is provided. The packaging method includes the following steps. In a step (a), a transparent substrate is provided. In a step (b), a transparent membrane circuit layer is formed on a surface of the transparent substrate. In a step (c), a semiconductor light emitting chip is formed on the transparent membrane circuit layer by a flip-chip mounting process, so that the semiconductor light emitting chip and the transparent membrane circuit layer are electrically connected with each other. In a step (d), an encapsulant is formed over the semiconductor light emitting chip to cover the semiconductor light emitting chip and a portion of the transparent membrane circuit layer. In a step (e), the encapsulant is baked.

Preferably, in the step (a), the transparent substrate is made of glass material, ceramic material, polysiloxane resin, polymethylmethacrylate, polyethylene terephthalate, polycarbonate, aluminum oxide or aluminum nitride.

Preferably, in the step (b), the transparent membrane circuit layer is made of a polymeric oxide, and the polymeric oxide is selected from ethylene-dioxythiphene)/poly(styrenesulfonate), indium tin oxide, indium zinc oxide, indium tin zinc oxide, hafnium oxide, zinc oxide, aluminum oxide, aluminum tin oxide, aluminum zinc oxide, cadmium tin oxide or cadmium zinc oxide.

Preferably, in the step (c), the semiconductor light emitting chip has a top surface, a bottom surface and plural lateral surfaces. The top surface and the bottom surface are opposed to each other. The plural lateral surfaces are arranged between the top surface and the bottom surface. A light beam is exited from the top surface and the plural lateral surfaces.

In an embodiment, at least one electric connection structure is formed between the bottom surface of the semiconductor light emitting chip and the transparent membrane circuit layer, and the semiconductor light emitting chip and the transparent membrane circuit layer are combined together through the at least one electric connection structure. The electric connection structure is made of transparent polymeric conductive material, silver paste, anisotropic conductive film, anisotropic conductive glue, or a combination thereof.

Preferably, in the step (d), the encapsulant is made of silicone, epoxy resin, epoxy/silicone mixed resin, polyurethane, or a combination thereof.

In accordance with another aspect of the present invention, a semiconductor light emitting unit is provided. The semiconductor light emitting unit includes a transparent substrate, a transparent membrane circuit layer and an encapsulant. The transparent membrane circuit layer is formed on a surface of the transparent substrate. The semiconductor light emitting chip is installed on the transparent membrane circuit layer by a flip-chip mounting process, so that the semiconductor light emitting chip and the transparent membrane circuit layer are electrically connected with each other. The encapsulant is formed over the semiconductor light emitting chip to cover the semiconductor light emitting chip and a portion of the transparent membrane circuit layer.

In an embodiment, the semiconductor light emitting chip has a top surface, a bottom surface and plural lateral surfaces. The top surface and the bottom surface are opposed to each other. The plural lateral surfaces are arranged between the top surface and the bottom surface. A light beam is exited from the top surface and the plural lateral surfaces.

In an embodiment, at least one electric connection structure is formed between the bottom surface of the semiconductor light emitting chip and the transparent membrane circuit layer, and the semiconductor light emitting chip and the transparent membrane circuit layer are combined together through the at least one electric connection structure. The electric connection structure is made of transparent polymeric conductive material, silver paste, anisotropic conductive film, anisotropic conductive glue, or a combination thereof.

In an embodiment, the transparent substrate is made of glass material, ceramic material, polysiloxane resin, polymethylmethacrylate, polyethylene terephthalate, polycarbonate, aluminum oxide or aluminum nitride.

In an embodiment, the transparent membrane circuit layer is made of a polymeric oxide, and the polymeric oxide is selected from ethylene-dioxythiphene)/poly(styrenesulfonate), indium tin oxide, indium zinc oxide, indium tin zinc oxide, hafnium oxide, zinc oxide, aluminum oxide, aluminum tin oxide, aluminum zinc oxide, cadmium tin oxide or cadmium zinc oxide.

In an embodiment, the encapsulant is formed as a transparent light-collecting structure.

In an embodiment, the encapsulant is formed as a transparent protective structure, and a surface of the transparent protective structure is in parallel with a surface of the semiconductor light emitting chip and a surface of the transparent membrane circuit layer.

In an embodiment, the encapsulant is made of silicone, epoxy resin, epoxy/silicone mixed resin, polyurethane, or a combination thereof.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a flowchart illustrating a packaging method of a semiconductor light emitting unit according to an embodiment of the present invention;

FIG. 2 schematically illustrates the packaging method of the semiconductor light emitting unit according to a first embodiment of the present invention; and

FIG. 3 schematically illustrates the packaging method of the semiconductor light emitting unit according to a second embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

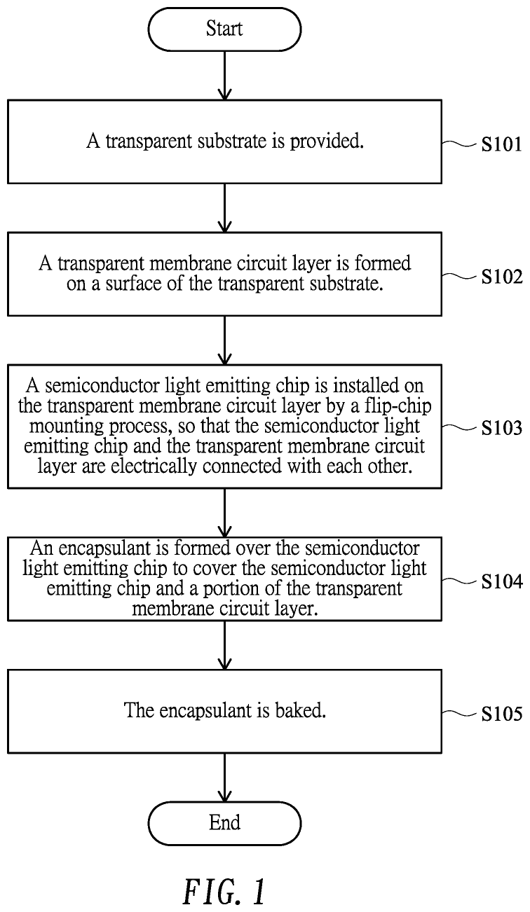

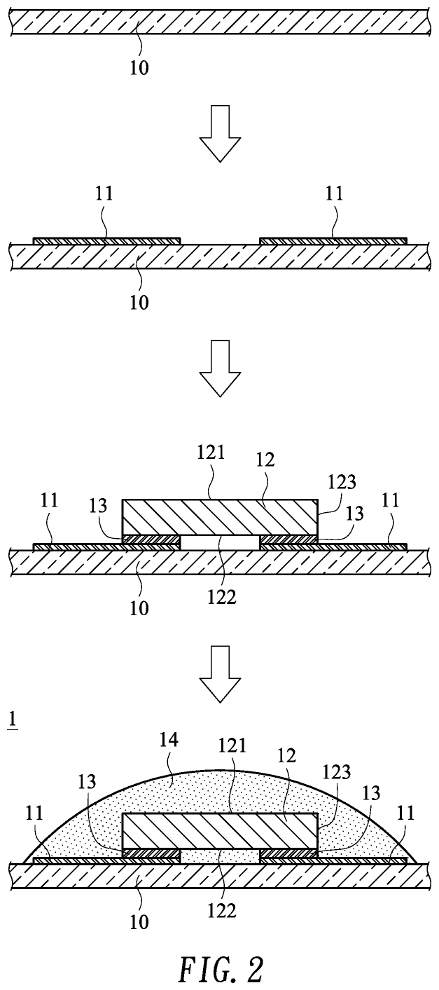

Please refer to FIGS. 1 and 2. FIG. 1 is a flowchart illustrating a packaging method of a semiconductor light emitting unit according to an embodiment of the present invention. FIG. 2 schematically illustrates the packaging method of the semiconductor light emitting unit according to a first embodiment of the present invention. The semiconductor light emitting unit of the present invention can be applied to a display module or illumination module of an electronic product. For example, the semiconductor light emitting unit is applied to an illumination module of a flexible electronic product, or applied to an illumination module of a sign light, an advertising light, a car light source, a locomotive light source, an outdoor/indoor lighting device, an interactive intelligent light source, indicator light source or a scenario light source. Moreover, plural semiconductor light emitting units may be arranged and combined according to the light-collecting properties corresponding to the shape and size of the encapsulant. Since the point optics, line optics or surface optics can be designed according to the practical requirements, the ultra-transparent luminous display effect can be achieved.

Hereinafter, the packing method of the present invention will be described with reference to the flowchart.

Firstly, a transparent substrate 10 is provided (Step S101). In the step S101, the transparent substrate 10 is made of glass material, ceramic material, polysiloxane resin, polymethylmethacrylate (PMMA), polyethylene terephthalate (PET), polycarbonate (PC), aluminum oxide or aluminum nitride. Moreover, the transmittance of the transparent substrate 10 is higher than 80%.

Then, a transparent membrane circuit layer 11 is formed on a surface of the transparent substrate 10 (Step S102). In the step S102, a polymeric oxide is formed on a surface of the transparent substrate 10 by performing an electroplating process, a wet coating process or a screen printing process and then performing a UV cure process or a baking cure process. Consequently, a film-like transparent membrane circuit layer 11 is formed on the surface of the transparent substrate 10. For example, the polymeric oxide is ethylene-dioxythiphene)/poly(styrenesulfonate) (PEDOT/PSS), indium tin oxide, indium zinc oxide, indium tin zinc oxide, hafnium oxide, zinc oxide, aluminum oxide, aluminum tin oxide, aluminum zinc oxide, cadmium tin oxide or cadmium zinc oxide, or a mixture of the foregoing polymer oxides.

Then, a semiconductor light emitting chip 12 is installed on the transparent membrane circuit layer 11 by a flip-chip mounting process, so that the semiconductor light emitting chip 12 and the transparent membrane circuit layer 11 are electrically connected with each other (Step S103). In the step S103, the semiconductor light emitting chip 12 has a top surface 121, a bottom surface 122 and plural lateral surfaces 123. The top surface 121 and the bottom surface 122 are opposed to each other. The plural lateral surfaces 123 are arranged between the top surface 121 and the bottom surface 122. In this embodiment, an electric connection structure 13 is formed between the bottom surface 122 of the semiconductor light emitting chip 12 and the transparent membrane circuit layer 11 by the flip-chip mounting process. The semiconductor light emitting chip 12 and the transparent membrane circuit layer 11 are combined together through the electric connection structure 13. Consequently, the semiconductor light emitting chip 12 and the transparent membrane circuit layer 11 are electrically connected with each other through the electric connection structure 13. In an embodiment, the electric connection structure 13 is made of transparent polymeric conductive material, silver paste, nano-silver paste, anisotropic conductive film, anisotropic conductive glue, or a combination thereof. Moreover, the light beams can be exited from the top surface 121 and the plural lateral surfaces 123.

Then, an encapsulant 14 is sprayed over the semiconductor light emitting chip 12 to cover the semiconductor light emitting chip 12 and a portion of the transparent membrane circuit layer 11 (Step S104). In the step S104, the encapsulant 14 is sprayed to the installation position of the semiconductor light emitting chip 12 by a contact dispensing processor or a jet dispensing process. In this embodiment, the encapsulant 14 is made of silicone, epoxy resin, epoxy/silicone mixed resin, polyurethane (PU), or the combination thereof. The encapsulant 14 has the viscosity in the range between 3500 cps and 12000 cps and the coefficient of thixotropy in the range between 2.5 and 4.0. In accordance with the present invention, the encapsulant 14 does not contain phosphor powder. Since the encapsulant 14 without phosphor powder which can be damaged by heating or water absorption, the luminous efficiency is not impaired.

Afterwards, the encapsulant 14 is baked (Step S105). In the step S105, the package structure of the transparent substrate 10 is placed into an oven with a microprocessor-based temperature controller. Moreover, the encapsulant 14 over the semiconductor light emitting chip 12 is subjected to a temperature control process, and thus the encapsulant 14 is solidified. In the temperature control process, the temperature is increased from 25° C. to 60° C. within 15 minutes, and then the encapsulant 14 is baked in a vacuum condition at 60° C. for 5 minutes so that the bubbles in the encapsulant 14 are removed. Then, the temperature is increased from 60° C. to 160° C. within 25 minutes. Then, the encapsulant 14 is baked at 160° C. for 90 minutes. After the temperature is decreased to 25° C., the encapsulant 14 is solidified and the semiconductor light emitting unit 1 is produced. In this embodiment, the solidified encapsulant 14 is a transparent light-collecting structure with protecting and light-collecting functions.

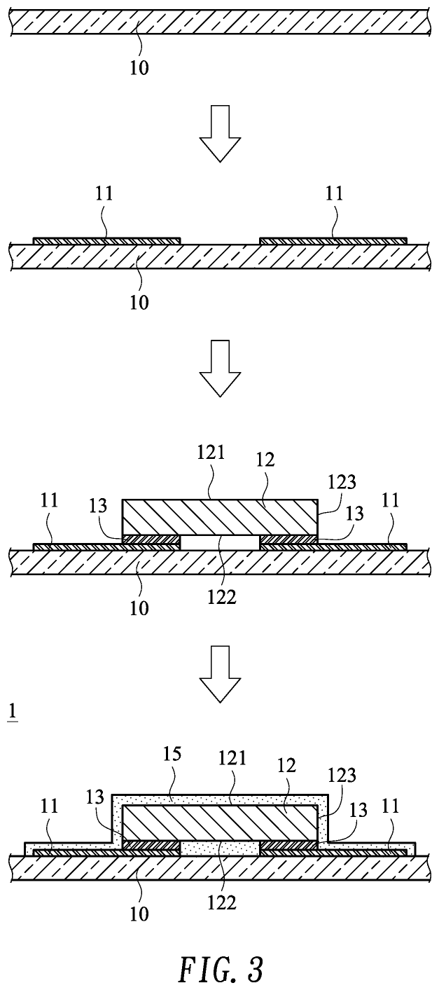

Please refer to FIGS. 1 and 3. FIG. 3 schematically illustrates the packaging method of the semiconductor light emitting unit according to a second embodiment of the present invention. The steps S101, S102 and S103 of the packaging method in FIG. 3 are identical to those of the packaging method in FIG. 2, and are not redundantly described herein. The step S104 is distinguished. In this embodiment, the encapsulant 14 has the viscosity in the range between 1500 cps and 5000 cps and the coefficient of thixotropy in the range between 1.2 and 2.0. The encapsulant 14 is sprayed to the installation position of the semiconductor light emitting chip 12 by a contact dispensing processor, a jet dispensing process or a print coating process. Consequently, an encapsulant 15 that is in parallel with the surface of the semiconductor light emitting chip 12 and the surface of the transparent membrane circuit layer 11 is formed. In the step S105, the temperature control process for baking the encapsulant 15 is distinguished. In the temperature control process, the temperature is increased from 25° C. to 40° C. within 15 minutes, and then the encapsulant 15 is baked in a vacuum condition at 40° C. for 30 minutes so that the bubbles in the encapsulant 15 are removed. Then, the temperature is increased from 40° C. to 80° C. within 20 minutes, and increased from 80° C. to 160° C. within 20 minutes. Then, the encapsulant 15 is baked at 160° C. for 60 minutes. After the temperature is decreased to 25° C., the encapsulant 15 is solidified and the semiconductor light emitting unit 1 is produced. In this embodiment, the solidified encapsulant 15 is a transparent protective structure, and the surface of the solidified encapsulant 15 is in parallel with the surface of the semiconductor light emitting chip 12 and the surface of the transparent membrane circuit layer 11. The transparent protective structure does not have the light-collecting function. However, the transparent protective structure has the function of protecting the inner portion of the semiconductor light emitting unit 1. Consequently, in the subsequent machining process, the possibility of causing the damage of the semiconductor light emitting unit 1 will be minimized.

In comparison with the conventional technology, the semiconductor light emitting unit and the packaging method of the present invention use the transparent membrane circuit layer to replace the conventional metallic conductive wires. Consequently, the light beams from the semiconductor light emitting unit are not obstructed by the transparent membrane circuit layer. In case that the semiconductor light emitting unit is applied to a display module or an illumination module, the transparence of the display module or the illumination module is increased and the luminous efficacy is enhanced. As previously described, the conventional wire bonding process has many drawbacks. For example, the wire is possibly broken or not well brazed, and the wire bonding tool may damage the semiconductor light emitting chip. The present invention uses the flip-chip mounting process to replace the conventional wire bonding process. The flip-chip mounting process can overcome the drawbacks of the conventional wire bonding process. Consequently, the yield of the semiconductor light emitting unit is enhanced. Moreover, since the light-outputting area is not hidden by the P electrode surface, the N electrode surface or the metallic conductive wires, the light-outputting area is largely enhanced. In other words, the technologies of the present invention are industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A packaging method of a semiconductor light emitting unit, the packaging method comprising steps of:
(a) providing a transparent substrate;
(b) forming a transparent membrane circuit layer on a surface of the transparent substrate;
(c) installing a semiconductor light emitting chip on the transparent membrane circuit layer by a flip-chip mounting process, so that the semiconductor light emitting chip and the transparent membrane circuit layer are electrically connected with each other;
(d) forming an encapsulant over the semiconductor light emitting chip to cover the semiconductor light emitting chip and a portion of the transparent membrane circuit layer; and
(e) baking the encapsulant.

2. The packaging method according to claim 1, wherein in the step (a), the transparent substrate is made of glass material, ceramic material, polysiloxane resin, polymethylmethacrylate, polyethylene terephthalate, polycarbonate, aluminum oxide or aluminum nitride.

3. The packaging method according to claim 1, wherein in the step (b), the transparent membrane circuit layer is made of a polymeric oxide, and the polymeric oxide is selected from ethylene-dioxythiphene)/poly(styrenesulfonate), indium tin oxide, indium zinc oxide, indium tin zinc oxide, hafnium oxide, zinc oxide, aluminum oxide, aluminum tin oxide, aluminum zinc oxide, cadmium tin oxide or cadmium zinc oxide.

4. The packaging method according to claim 1, wherein in the step (c), the semiconductor light emitting chip has a top surface, a bottom surface and plural lateral surfaces, wherein the top surface and the bottom surface are opposed to each other, the plural lateral surfaces are arranged between the top surface and the bottom surface, and a light beam is exited from the top surface and the plural lateral surfaces.

5. The packaging method according to claim 4, wherein at least one electric connection structure is formed between the bottom surface of the semiconductor light emitting chip and the transparent membrane circuit layer, and the semiconductor light emitting chip and the transparent membrane circuit layer are combined together through the at least one electric connection structure, wherein the electric connection structure is made of transparent polymeric conductive material, silver paste, anisotropic conductive film, anisotropic conductive glue, or a combination thereof.

6. The packaging method according to claim 1, wherein in the step (d), the encapsulant is made of silicone, epoxy resin, epoxy/silicone mixed resin, polyurethane, or a combination thereof.

7. A semiconductor light emitting unit, comprising:
a transparent substrate;
a transparent membrane circuit layer formed on a surface of the transparent substrate;
a semiconductor light emitting chip installed on the transparent membrane circuit layer by a flip-chip mounting process, so that the semiconductor light emitting chip and the transparent membrane circuit layer are electrically connected with each other; and
an encapsulant formed over the semiconductor light emitting chip to cover the semiconductor light emitting chip and a portion of the transparent membrane circuit layer.

8. The semiconductor light emitting unit according to claim 7, wherein the semiconductor light emitting chip has a top surface, a bottom surface and plural lateral surfaces, wherein the top surface and the bottom surface are opposed to each other, the plural lateral surfaces are arranged between the top surface and the bottom surface, and a light beam is exited from the top surface and the plural lateral surfaces.

9. The semiconductor light emitting unit according to claim 8, wherein at least one electric connection structure is formed between the bottom surface of the semiconductor light emitting chip and the transparent membrane circuit layer, and the semiconductor light emitting chip and the transparent membrane circuit layer are combined together through the at least one electric connection structure, wherein the electric connection structure is made of transparent polymeric conductive material, silver paste, anisotropic conductive film, anisotropic conductive glue, or a combination thereof.

10. The semiconductor light emitting unit according to claim 7, wherein the transparent substrate is made of glass material, ceramic material, polysiloxane resin, polymethylmethacrylate, polyethylene terephthalate, polycarbonate, aluminum oxide or aluminum nitride.

11. The semiconductor light emitting unit according to claim 7, wherein the transparent membrane circuit layer is made of a polymeric oxide, and the polymeric oxide is selected from ethylene-dioxythiphene)/poly(styrenesulfonate), indium tin oxide, indium zinc oxide, indium tin zinc oxide, hafnium oxide, zinc oxide, aluminum oxide, aluminum tin oxide, aluminum zinc oxide, cadmium tin oxide or cadmium zinc oxide.

12. The semiconductor light emitting unit according to claim 7, wherein the encapsulant is formed as a transparent light-collecting structure.

13. The semiconductor light emitting unit according to claim 7, wherein the encapsulant is formed as a transparent protective structure, and a surface of the transparent protective structure is in parallel with a surface of the semiconductor light emitting chip and a surface of the transparent membrane circuit layer.

14. The semiconductor light emitting unit according to claim 7, wherein the encapsulant is made of silicone, epoxy resin, epoxy/silicone mixed resin, polyurethane, or a combination thereof.
